(19) United States
(12) Patent Application Publication
(10) Pub. No.: US 2008/0079133 A1
(43) Pub. Date: Apr. 3, 2008

(54) Stack type semiconductor device package

(76) Inventor: Chang-Young Park, Anyang-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/636,985

(22) Filed: Dec. 12, 2006

(30) Foreign Application Priority Data
Oct. 3, 2006 (KR) 2006-97468

(51) Int. Cl. H01L 23/48

(52) U.S. Cl. 257/690

(57) ABSTRACT

A stack type semiconductor device package is disclosed having first and second semiconductor device packages mounted in a mirror arrangement on opposing first and second surfaces of an interposer, wherein the first and second semiconductor device packages and the first and second surfaces of the interposer are, respectively, adapted for connection using a land grid array method.

### BACKGROUND OF THE INVENTION

1. Field of Invention

The present invention relates to a semiconductor device package, and more particularly to a stack type semiconductor device package.

This application claims priority under 35 U.S.C. § 119 to Korean Patent Application No. 2006-97468, filed on Oct. 3, 2006, the subject matter of which is hereby incorporated by reference.

2. Discussion of Related Art

Reduce in overall size of contemporary semiconductor devices is an important design objective. Various packaging types, such as a fine pitch ball grid array (FBGA) packages and a chip scale packages (CSP), have been developed to provide relatively small packages while also providing a relatively large number of connection pins. These and similar package types allow small but highly competent semiconductor devices which find application in portable electric devices.

Unfortunately, while emerging semiconductor device package types (e.g., FBGA or CSP) provide notable advantages in reducing the size and weight of the overall device, such advantages often come at the cost of device reliability. Additionally, emerging semiconductor device package types suffer from a lack of cost competitiveness due to their more costly materials and manufacturing requirements. This is particularly true of the micro ball grid array (μ BGA) package type.

One technique referred to as wafer level CSP (WL-CSP) attempts to address the foregoing disadvantages. This packaging technique is characterized by the use of the redistribution or rerouting of various bonding pads in the semiconductor device. During fabrication of a WL-CSP device, closely spaced bonding pad connections are redistributed over a semiconductor substrate to access relatively larger bonding pads. An outer connection terminal, such as one adapted to receive a solder ball, is then commonly associated with the larger bonding pads.

However, as contemporary semiconductor devices become ever more highly integrated, the available surface area allocated to packaging connections and device integration ultimately fails, at least in two dimensions. Further increases in semiconductor device density have motivated designers to build-up the devices vertically (a third integration dimension).

Stack type semiconductor device packages are one type of vertical integration solution. In the context of a semiconductor memory device, stack type devices allow greater storage capacity per unit of device surface area. However, the use of stack type semiconductor devices is becoming constrained in portable electronic devices because of height (vertical profile) limitations.

It should be noted that an additional connection terminal is commonly provided on the edge of printed circuit boards (PCBs) designed to receive stack type semiconductor devices. The additional connection terminal tends to increase the overall area size of a semiconductor device. Additionally, this additional outer connection terminal defines a minimum separation distance between the stacked elements in the stack type semiconductor device. The additional connection terminal is also subject to external impact and associated failures.

Moreover, many contemporary semiconductor device designs make use of a lead frame. That is, a lead frame is commonly required to electrically connect the stack type semiconductor device (e.g., mount the stack type semiconductor device on a system board). Incorporation of a lead frame consumes additional vertical height margin in the stack type semiconductor device. All of the foregoing conventionally precludes reduction in the height of a stack type semiconductor device below some critical minimum height. These height restrictions and continuing concerns over susceptibility of conventional stack type semiconductor devices pose real design limitations as the vertical profile of many portable electronic devices becomes increasingly small.

### SUMMARY OF THE INVENTION

Embodiments of the invention provide a stack type semiconductor device package enjoying improved resistance to external impacts. Embodiments of the invention also provide a stack type semiconductor device package having reduced size and thickness.

In one embodiment, the invention provides a stack type semiconductor device package, comprising; first and second semiconductor device packages mounted in a mirror arrangement on opposing first and second surfaces of an interposer, wherein the first and second semiconductor device packages and the first and second surfaces of the interposer are, respectively, adapted for connection using a land grid array method.

In another embodiment, the each one of the first and second semiconductor device packages comprises; a semiconductor chip having bonding pads, a printed circuit board having first and second surfaces, the first surface adapted to mount the semiconductor chip and comprising bonding electrodes, and the second surface comprising joining electrodes, bonding wires respectively connecting the bonding electrodes and the bonding pads, and a molding material sealing the first surface of the printed circuit board, the semiconductor chip, and the bonding wires.

In another embodiment, the first and second semiconductor device packages are connected to a system board via the interposer. The interposer in related embodiments may be a lead frame type interposer or a substrate type interposer.

In another embodiment, a connected system board comprises an embedded type mounting structure adapted to receive and mount the interposer.

### BRIEF DESCRIPTION OF THE FIGURES

Figure (FIG.) 1 is a sectional view of a semiconductor device package according to an embodiment of the invention;

FIG. 2 is a sectional view of a stack type semiconductor device package according to an embodiment of the invention;

FIG. 3A is a sectional view of a stack type semiconductor device package according to another embodiment of the invention; and

FIG. 3B is a perspective view of the stack type semiconductor device package of FIG. 3A mounted on a system board.

### DESCRIPTION OF EMBODIMENTS

Several embodiments of the invention will be described in some additional detail with reference to the accompanying drawings. The present invention may, however, be embodied in different forms and should not be constructed as being limited to only the illustrated embodiments. Rather, these embodiments are presented as teaching examples.

In the figures, the illustrated dimensions of various layers and regions may be exaggerated for clarity. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals are used throughout the written description and drawings to refer to like or similar elements.

FIG. 1 is a sectional view of a semiconductor device package according to an embodiment of the invention.

Referring to FIG. 1, a semiconductor device package includes stacked semiconductor chips 110a, 110b, 110c, and 110d, a printed circuit board (PCB) 120, bonding wires 130a, 130b, 130c, and 130d, and a molding material 140. Bonding pads 112a, 112b, 112c, and 112d are formed on the stacked semiconductor chips 110a, 110b, 110c, and 110d, respectively. An upper insulation layer pattern 122 and bonding electrodes 124 corresponding to the bonding pads 112a, 112b, 112c, and 112d are formed on the PCB 120. The bonding wires 130a, 130b, 130c, and 130d electrically connect the bonding electrodes 124 to the corresponding bonding pads 112a, 112b, 112c, and 112d. Additionally, the molding material 140 seals the PCB 120, the stacked semiconductor chips 110a, 110b, 110c, and 110d, and the bonding wires 130a, 130b, 130c, and 130d. In the illustrated example, the foregoing is formed on a first surface of PCB 120.

In contrast, a lower insulation layer pattern 126 and joining electrodes 128 are formed on a second surface of PCB 120 opposite the first surface. The joining electrodes 128 electrically connect the PCB 120 and an interposer. That is, the first surface of PCB 120 includes stacked semiconductor chips 110a, 110b, 110c, and 110d arranged in a conventional land grid array package structure. This type of land grid array package structure has been successfully applied to semiconductor device packages requiring a high degree of integration, such as flash memory. Stacked semiconductor chips 110a, 110b, 110c, and 110d may be mounted onto PCB 120 having upper insulation layer pattern 122 by using one or more conventionally available adhesive materials. In one embodiment, upper insulation layer pattern 122 may be formed from a photo solder resist (PSR).

Bonding pads 112a, 112b, 112c, and 112d of stacked semiconductor chips 110a, 110b, 110c, and 110d are respectively connected to one of bonding pads 112a, 112b, and 112c or bonding electrodes 124.

Molding material 140 seals the first surface of PCB 120 to cover stacked semiconductor chips 110a, 110b, 110c, and 110d, and bonding wires 130a, 130b, 130c, and 130d. In one embodiment, molding material 140 may be an epoxy molding compound (EMC).

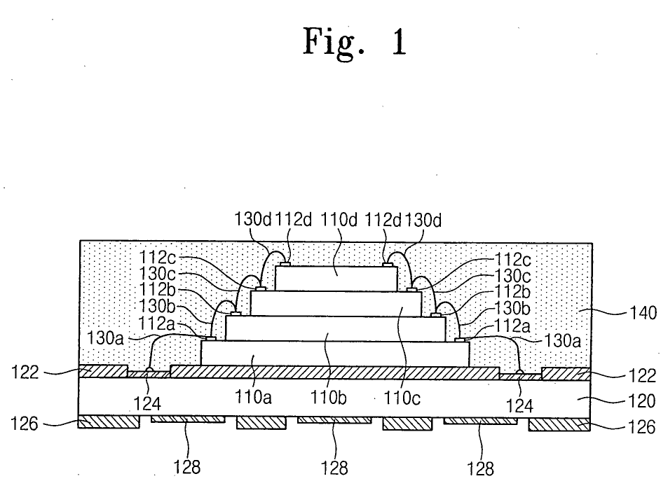

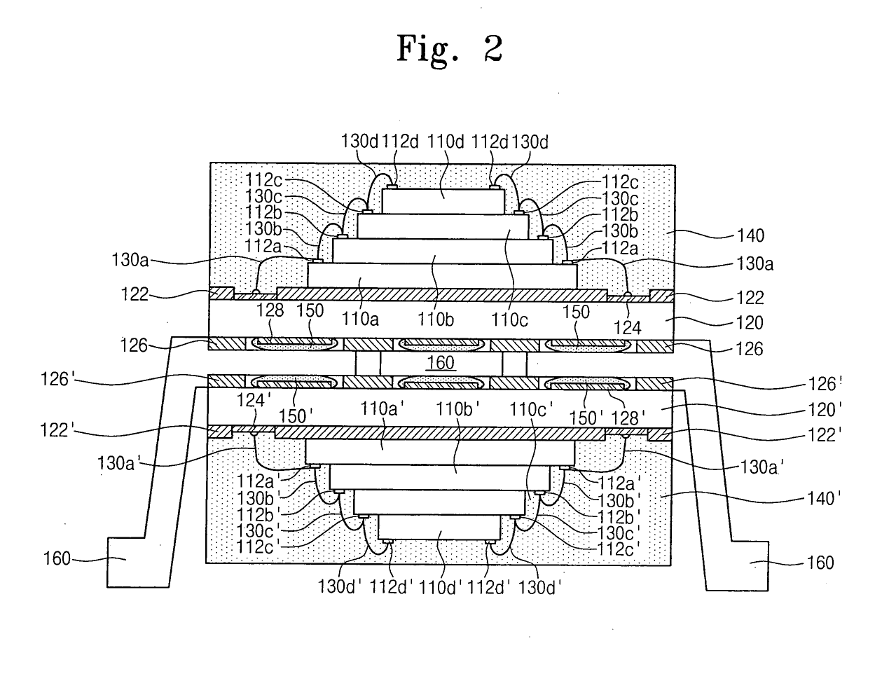

FIG. 2 is a sectional view of a stack type semiconductor device package according to an embodiment of the invention.

Referring to FIG. 2, a stack type semiconductor device package includes first and second semiconductor device packages having a structure such as the one shown in FIG. 1. An interposer 160 is disposed between the first and second semiconductor device packages. In one embodiment, interposer 160 is a lead frame.

The first and second semiconductor device packages may be mounted, respectively on first and second surfaces of interposer 160 using, for example, a land grid array method. Joining electrodes 128 are provided to facilitate various electrical connections for PCB 120 in relation to interposer 160 and may include pre-solders 150. Pre-solders 150 may be used to improve the connection reliability between joining electrodes 128 and interposer 160. In one embodiment, pre-solder 150 may be a SnAgCu alloy.

In the illustrated embodiment, the first and second semiconductor packages are mounted on interposer 160 in a mirror structure. The stack type semiconductor device package can be manufactured to have a mirror structure by considering a process of manufacturing semiconductor chips 110a and 110a′, 110b and 110b′, 110c and 110c′, and 110d and 110d′. Moreover, the stack type semiconductor device package can be manufactured to have a mirror structure by considering a process of manufacturing a rerouting circuits (not shown) of the PCBs 120 and 120′ and using the semiconductor chips 110a and 110a′, 110b and 110b′, 110c and 110c′, and 110d and 110d′ are identical each other.

The stack type semiconductor device including mirror-mounted first and second semiconductor device packages may subsequently be electrically connected to and mechanically mounted on a system board (not shown) using interposer 160. That is, interposer 160 may be provided with a length beyond the lateral extension of the first and second semiconductor device packages to provide one or more ends adapted to a tape automated bonding (TAB) type connection process, or a gull wing type connection points. In this manner, interposer 160 may provide various electrical connections between the system board and the first and second semiconductor device packages. Although not shown in the illustrated cross-section, PCBs 120 and 120′ may include a chip selection pin (C/S pin) adapted to select (i.e., drive) one or more semiconductor chips in the first and second semiconductor device packages in response to a signal received from the system board.

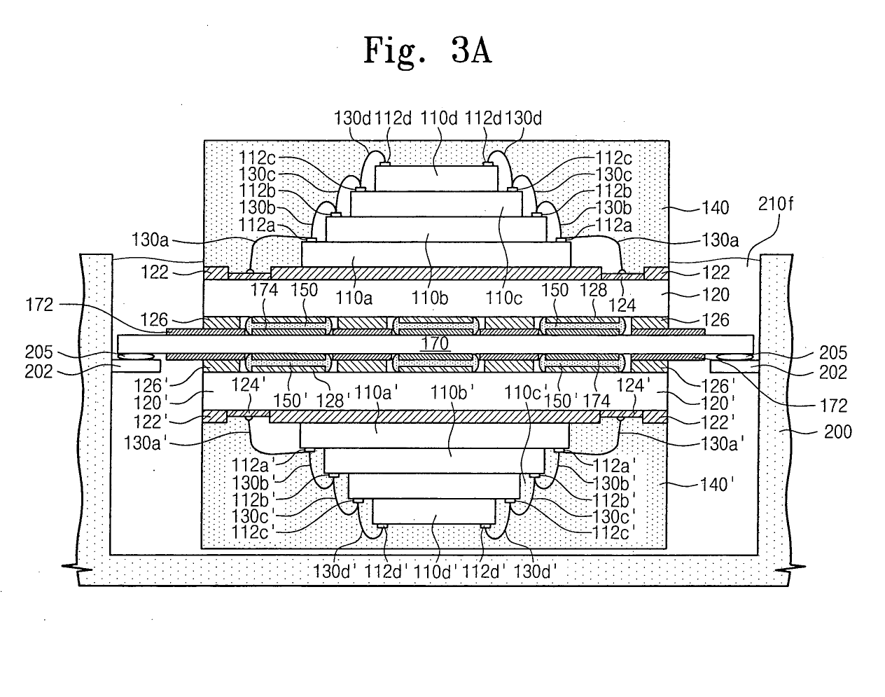

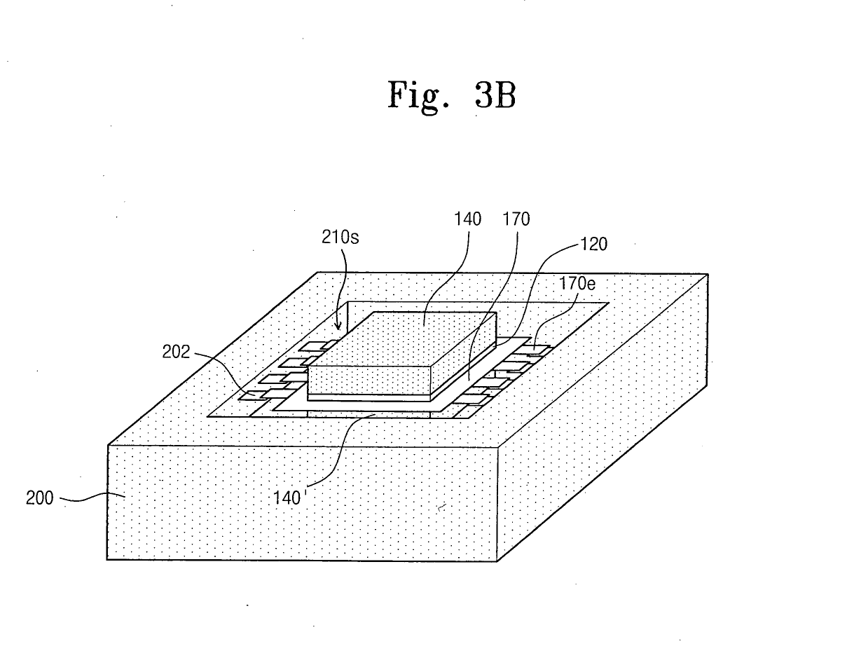

FIG. 3A is a sectional view of a stack type semiconductor device package according to an embodiment of the invention. FIG. 3B is a perspective view of the stack type semiconductor device package of FIG. 3A mounted on a system board.

Referring to FIGS. 3A and 3B, a stack type semiconductor device package includes first and second semiconductor device packages having a structure identical to that of FIG. 1, and an interposer 170 disposed in the first and second semiconductor device packages. The interposer 170 may be a substrate type. The first and second semiconductor device packages may be mounted on first and second surfaces of the interposer 170 by using a land grid array method.

The first and second semiconductor device packages may be fabricated with a common or a unique structure. Once fabricated the first and second semiconductor device packages may thereafter be connected in a mirror structure on an interposer 170.

The stack type semiconductor device package may be manufactured to have a mirror structure by considering a process of manufacturing semiconductor chips 110a and 110a′, 110b and 110b′, 110c and 110c′, and 110d and 110d′. Moreover, the stack type semiconductor device package can be manufactured to have a mirror structure by considering a process of manufacturing a rerouting circuits (not shown) associated with PCBs 120 and 120′ or a rerouting circuit (not shown) associated with interposer 170. In one embodiment, semiconductor chips 110a and 110a′, 110b and 110b′, 110c and 110c′, and 110d and 110d′ may be respectively identical.

The first and second semiconductor device packages are electrically connected to and mounted on a system board 200 using mechanical/electrical connections provided on interposer 170.

First and second surface insulation layer patterns 172 may be provided on the first and second surfaces of interposer 170 to define solder lands 174 and to insulate the first and second semiconductor device packages. Interposer 170 may further include solder lands 174 on its first and second surfaces. Solder lands 174 are adapted to be electrically connected to joining electrodes 128 and 128′ of the first and second semiconductor device packages. Moreover, solder lands 174 may include pre-solders 150 to improve connection reliability between joining electrodes 128 and 128′ and the first and second semiconductor device packages. Additionally, interposer 170 may further include connection electrodes 170e (see, FIG. 3B) to electrically connect system board 200. Although not shown in the illustration, PCBs 120 and 120′ may further include a chip selection pin (C/S pin) driving one or more of the semiconductor chips in response to a signal received from system board 200.

System board 200 may include an embedded type mounting structure 210s adapted to receive and connect interposer 170. Additionally, system board 200 may further include connection terminals 202 of various geometries adapted to protruding to electrically connect with connection electrodes 170e of interposer 170 within embedded mounting structure 210s. In one embodiment, connection electrodes 170e of interposer 170 may be connected to connection terminals 202 of system board 200 by associated joining elements 205. Such joining elements 205 may be made from a solder material.

Once Interposer 170 together with first and second semiconductor device packages is mounted on connection terminals 202 of system board 200 using joining elements 205, a protective material 210f may be further provided to fill and seal embedded type mounting structure 210s, the first and second semiconductor device packages, interposer 170, and connection terminals 202. Protective material 210f may be used to improve reliability between connection electrodes 170e of interposer 170 and connection terminals 202 of system board 200.

Embodiments of the present invention provides a stack type semiconductor device package having a structure in which the semiconductor device packages having a mirror structure are mounted on an interposer by using a land grid array method. Such packages are more resistant to external impacts while at the same time reducing the overall size and thickness of the package. The resulting stack type semiconductor device package has improved integration and physical reliability.

The above-disclosed subject matter is to be considered illustrative, and not restrictive, and the appended claims are intended to cover the modifications, enhancements, and other embodiments apparent to those of ordinary skill in the art.

What is claimed is:

1. A stack type semiconductor device package, comprising:
first and second semiconductor device packages mounted in a mirror arrangement on opposing first and second surfaces of an interposer,
wherein the first and second semiconductor device packages and the first and second surfaces of the interposer are, respectively, adapted for connection using a land grid array method.

2. The stack type semiconductor device package of claim 1, wherein each one of the first and second semiconductor device packages comprise:
a semiconductor chip having bonding pads;
a printed circuit board having first and second surfaces, the first surface adapted to mount the semiconductor chip and comprising bonding electrodes, and the second surface comprising joining electrodes;
bonding wires respectively connecting the bonding electrodes and the bonding pads; and
a molding material sealing the first surface of the printed circuit board, the semiconductor chip, and the bonding wires.

3. The stack type semiconductor device package of claim 2, further comprising:
at least one additional semiconductor chip stacked on the semiconductor chip and having respective bonding pads.

4. The stack type semiconductor device package of claim 3, wherein bonding pads of the additional semiconductor chip are respectively connected to corresponding bonding pads of the semiconductor chip or a corresponding bonding electrode.

5. The stack type semiconductor device package of claim 2, wherein the joining electrode comprises a pre-solder.

6. The stack type semiconductor device package of claim 2, wherein the molding material is an epoxy molding compound.

7. The stack type semiconductor device package of claim 1, wherein the first and second semiconductor device packages are connected to a system board via the interposer.

8. The stack type semiconductor device package of claim 7, wherein the interposer comprises first and second surfaces, each having solder lands adapted to electrically connect with the joining electrodes of the first and second semiconductor device packages.

9. The stack type semiconductor device package of claim 8, wherein the solder land comprises a pre-solder.

10. The stack type semiconductor device package of claim 8, wherein the interposer comprises a lead frame type interposer or a substrate type interposer.

11. The stack type semiconductor device package of claim 10, wherein the interposer is the lead frame type interposer and comprises at least one end adapted to a tape automated bonding type connection.

12. The stack type semiconductor device package of claim 11, wherein the interposer further comprises a gull wing section associated with the at least one end.

13. The stack type semiconductor device package of claim 10, wherein the interposer is the substrate type interposer and comprises at least one connection electrode adapted to be electrically connected to the system board.

14. The stack type semiconductor device package of claim 13, wherein the interposer further comprises a chip selection pin.

15. The stack type semiconductor device package of claim 13, wherein the system board comprises an embedded type mounting structure adapted to receive and mount the interposer.

16. The stack type semiconductor device package of claim 15, wherein the system board further comprises connection terminals adapted to electrically connect the connection electrodes within the embedded type mounting structure.

17. The stack type semiconductor device package of claim 14, further comprising a protective material sealing the embedded type mounting structure, the first and second semiconductor device packages, the interposer, and the connection terminals.
